(19) United States
(12) Patent Application Publication
(10) Pub. No.: US 2020/0225185 A1
(43) Pub. Date: Jul. 16, 2020

(54) SENSOR INCLUDING NANOSTRUCTURES AND METHOD FOR MANUFACTURING THE SAME

(71) Applicant: KOREA ADVANCED INSTITUTE OF SCIENCE AND TECHNOLOGY, Daejeon (KR)

(72) Inventors: Hee-Tae JUNG, Daejeon (KR); Hohyung KANG, Daejeon (KR); Heeeun JOO, Daejeon (KR); Soo Yeon CHO, Daejeon (KR); Woo-Bin JUNG, Daejeon (KR)

(21) Appl. No.: 16/742,987

(22) Filed: Jan. 15, 2020

(30) Foreign Application Priority Data
Jan. 15, 2019 (KR) 10-2019-0005419

(51) Int. Cl. G01N 27/407; G01N 27/416; H01L 21/3065; G01N 27/12

(52) U.S. Cl. CPC G01N 27/407; G01N 27/127; H01L 21/3065; G01N 27/416

(57) ABSTRACT

The present disclosure relates to a sensor including a nanostructure and a method for manufacturing the same.

### CROSS-REFERENCE TO RELATED APPLICATION

This application claims the benefit under 35 USC 119(a) of Korean Patent Applications No. 10-2019-0005419 filed on Jan. 15, 2019 in the Korean Intellectual Property Office, the entire disclosures of which are incorporated herein by reference for all purposes.

### TECHNICAL FIELD

The present disclosure relates to a sensor including a nanostructure and a method for manufacturing the same.

### BACKGROUND

A gas sensor is a device that detects a specific component contained in a gas and converts it into an appropriate electrical signal according to the concentration. Gas sensors can be classified into electrochemical type, semiconductor type, catalytic combustion type or optical type by the gas detection method.

Particularly, a hydrogen sulfide gas sensor is required to have a fast response time since hydrogen sulfide needs to be sensed before the concentration increases to 4% or more. Conventional gas sensors still have a slow response time to 1% hydrogen sulfide at room temperature.

Prior Art Document 1: Korean Patent Laid-open Publication No. 10-2014-0104784

### SUMMARY

In view of the foregoing, the present disclosure provides a sensor including an array of at least one nanostructure including a sensing material.

However, problems to be solved by the present disclosure are not limited to the above-described problems. Although not described herein, other problems to be solved by the present disclosure can be clearly understood by a person with ordinary skill in the art from the following descriptions.

A first aspect of the present disclosure provides a sensor including an array of at least one nanostructure including a sensing material.

A second aspect of the present disclosure provides a method of manufacturing a sensor according to the first aspect of the present disclosure, including (a) depositing a sensing material on a substrate on which a prepattern is formed, (b) re-depositing the sensing material on the side of the prepattern by an ion etching process to form a nanopattern; and (c) removing the prepattern by an ion etching process to form nanostructures.

A nanostructure according to embodiments of the present disclosure is manufactured through a simple process at low cost by applying an ion bombardment occurring during physical ion etching, and has various shapes with a line width of up to 10 nm. Therefore, it can be usefully applied to a sensor that requires excellent sensitivity.

A sensor including a nanostructure according to embodiments of the present disclosure may use, as a sensing material, a single component, a binary material and/or a ternary material in various ways and can be usefully applied to a sensor that requires a high sensitivity and a fast response/recovery rate by controlling the aspect ratio, resolution and grain size of the nanostructure in various ways. Particularly, a sensor including a nanostructure containing SnO₂, SiO₂/NiO or SnO₂/Au has a remarkably high response amplitude (Rₐᵢᵣ/Rₐ) and an excellent response time/recovery time when a hydrogen sulfide gas is detected.

A method of manufacturing a sensor including a nanostructure according to embodiments of the present disclosure can change a component, a content ratio, or a shape of a sensing material to be re-deposited through a simple process change by adjusting an order of deposition, a thickness of the deposition or the number of the deposition while depositing the sensing material or adjusting an angle of ion etching process or a time of the ion etching process after the deposition. Thus, it is possible to easily manufacture a nanostructure for sensor having a high sensitivity and a fast response/recovery rate.

### BRIEF DESCRIPTION OF THE DRAWINGS

In the detailed description that follows, embodiments are described as illustrations only since various changes and modifications will become apparent to a person with ordinary skill in the art from the following detailed description. The use of the same reference numbers in different figures indicates similar or identical items.

FIG. 1 is a schematic diagram illustrating a manufacturing process of a line-shaped nanostructure in accordance with an example of the present disclosure.

FIG. 2 is a graph showing the dynamic sensing response of a sensor including a line-shaped nanostructure containing SnO₂ to a hydrogen sulfide gas in accordance with an example of the present disclosure.

FIG. 3 is a graph showing the selectivity of a sensor including a line-shaped nanostructure containing SnO₂ to a hydrogen sulfide gas in accordance with an example of the present disclosure.

FIG. 4 is a graph showing the dynamic sensing response of a sensor including a line-shaped nanostructure containing SiO₂/NiO (molar ratio of 28:2) to a hydrogen sulfide gas in accordance with an example of the present disclosure.

FIG. 5 is a graph showing the dynamic sensing response of a sensor including a line-shaped nanostructure containing SiO₂/Au (molar ratio of 29:1) to a hydrogen sulfide gas in accordance with an example of the present disclosure.

FIG. 6 is a graph showing the dynamic sensing response of a sensor including a line-shaped nanostructure containing SiO₂/Au (molar ratio of 28:2) to a hydrogen sulfide gas in accordance with an example of the present disclosure.

FIG. 7 is a graph showing the selectivity of a sensor including a line-shaped nanostructure containing SiO₂/Ni (molar ratio of 28:2) to a hydrogen sulfide gas in accordance with an example of the present disclosure.

FIG. 8 is a graph showing the selectivity of a sensor including a line-shaped nanostructure containing SiO₂/Au (molar ratio of 29:1) to a hydrogen sulfide gas in accordance with an example of the present disclosure.

FIG. 9 is a graph showing the selectivity of a sensor including a line-shaped nanostructure containing SiO₂/Au (molar ratio of 28:2) to a hydrogen sulfide gas in accordance with an example of the present disclosure.

FIG. 10A is a graph showing the dynamic sensing response of a sensor including a line-shaped nanostructure containing Au to a hydrogen sulfide gas at room temperature in accordance with a comparative example of the present disclosure.

FIG. 10B is a graph showing the dynamic sensing response of a sensor including a line-shaped nanostructure containing Au/Cu (molar ratio of 1:1) to a hydrogen sulfide gas at room temperature in accordance with a comparative example of the present disclosure.

FIG. 10C is a graph showing the dynamic sensing response of a sensor including a line-shaped nanostructure containing Au/Pd (molar ratio of 1:1) to a hydrogen sulfide gas at room temperature in accordance with a comparative example of the present disclosure.

FIG. 10D is a graph showing the dynamic sensing response of a sensor including a line-shaped nanostructure containing Au/Pd (molar ratio of 7:3) to a hydrogen sulfide gas at room temperature in accordance with a comparative example of the present disclosure.

FIG. 10E is a graph showing the dynamic sensing response of a sensor including a line-shaped nanostructure containing Au/Pd (molar ratio of 9:1) to a hydrogen sulfide gas at room temperature in accordance with a comparative example of the present disclosure.

FIG. 11A is a graph showing the dynamic sensing response of a sensor including a line-shaped nanostructure containing Au/Pd (molar ratio of 1:1) to a hydrogen sulfide gas at 75° C. in accordance with a comparative example of the present disclosure.

FIG. 11B is a graph showing the dynamic sensing response of a sensor including a line-shaped nanostructure containing Au/Pd (molar ratio of 7:3) to a hydrogen sulfide gas at 75° C. In accordance with a comparative example of the present disclosure.

FIG. 11C is a graph showing the dynamic sensing response of a sensor including a line-shaped nanostructure containing Au/Pd (molar ratio of 9:1) to a hydrogen sulfide gas at 75° C. in accordance with a comparative example of the present disclosure.

FIG. 12 is a graph showing the dynamic sensing response of a sensor including a line-shaped nanostructure containing SnO₂/Pt (molar ratio of 25:1) to a hydrogen sulfide gas at 300° C. in accordance with an example of the present disclosure.

FIG. 13A is a graph showing the dynamic sensing response of a sensor including a line-shaped nanostructure containing SnO₂/Au (molar ratio of 25:1) to a hydrogen sulfide gas at 300° C. in accordance with an example of the present disclosure.

FIG. 13B is a graph showing the dynamic sensing response of a sensor including a line-shaped nanostructure containing SnO_{Z}/Au (molar ratio of 25:0.5) to a hydrogen sulfide gas at 300° C. In accordance with an example of the present disclosure.

FIG. 14A is a graph showing the dynamic sensing response of a sensor including a line-shaped nanostructure containing WO₃ to a hydrogen sulfide gas at 300° C. in accordance with an example of the present disclosure.

FIG. 14B is a graph showing the dynamic sensing response of a sensor including a line-shaped nanostructure containing WO₃/Au (molar ratio of 25:1) to a hydrogen sulfide gas at 300° C. in accordance with an example of the present disclosure.

FIG. 14C is a graph showing the dynamic sensing response of a sensor including a line-shaped nanostructure containing WO₃/Pt (molar ratio of 25:1) to a hydrogen sulfide gas at 300° C. in accordance with an example of the present disclosure.

FIG. 15 is a graph showing the affinity and adsorbability of a sensor including a line-shaped nanostructure containing SnO₂ to hydrogen sulfide gas molecules depending on the presence of Au in accordance with an example of the present disclosure.

FIG. 16 is a graph showing the adsorbability of a sensor including a line-shaped nanostructure containing SnO₂/Au (molar ratio of 15:1), SnO₂, SnO₂/NiO (molar ratio of 15:1) to hydrogen sulfide gas molecules in accordance with an example of the present disclosure.

### DETAILED DESCRIPTION

Throughout the whole document, the term “connected to” may be used to designate a connection or coupling of one element to another element and includes both an element being “directly connected to” another element and an element being “electronically connected to” another element via another element.

Through the whole document, the term “on” that is used to designate a position of one element with respect to another element includes both a case that the one element is adjacent to the other element and a case that any other element exists between these two elements.

Further, it is to be understood that the term “comprises or includes” and/or “comprising or including” used in the document means that one or more other components, steps, operation and/or the existence or addition of elements are not excluded from the described components, steps, operation and/or elements unless context dictates otherwise; and is not intended to preclude the possibility that one or more other features, numbers, steps, operations, components, parts, or combinations thereof may exist or may be added. The term “about or approximately” or “substantially” are intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination(s) of”” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

A gas response amplitude (Rₐᵢᵣ/Rₐ) is defined as a ratio of the resistance (Rₐᵢᵣ) to air to the resistance to a gas (H₂S).

Hereinafter, embodiments and examples of the present disclosure will be described in detail. However, the present disclosure may not be limited to the following embodiments and examples.

A first aspect of the present disclosure provides a sensor including an array of at least one nanostructure including a sensing material.

In an embodiment of the present disclosure, the sensing material may detect a hydrogen sulfide (H₂S) gas, but may not be limited thereto.

In an embodiment of the present disclosure, the nanostructure is manufactured using an ion bombardment in which particles of a physically bombarded target material are scattered in all directions. Specifically, a nanostructure having a high aspect ratio and uniformity is manufactured in large area by providing a patterned prepattern having an outer surface to which particles of a sensing material are attached and removing only the prepattern from a sensing material-prepattern composite structure formed by attaching the sensing material particles scattered from the sensing material by the ion bombardment to the outer surface of the prepattern.

In an embodiment of the present disclosure, the shape of the nanostructure may be selected from the group consisting of line pattern, lattice shape, curved shape, cylinder shape, square column shape, reciprocal cone shape, cuboid shape, top shape, cup shape and c-shape, but may not be limited thereto.

In an embodiment of the present disclosure, the nanostructure may be tilted at about 30° to about 90° with respect to a substrate or a partial upper portion of the nanostructure may be folded at about 30° to about 90° with respect to the substrate. The substrate is a flat plate and may be made of any material that does not undergo physical deformation caused by the temperature and pressure of a lithography process. Specifically, the substrate may be made of a material selected from the group consisting of silicon, silicon oxide, quartz, glass, and mixtures thereof, but may not be limited thereto.

In an embodiment of the present disclosure, the shape of the nanostructure may be lamella shape or nanoporous cylinder shape, but may not be limited thereto.

In an embodiment of the present disclosure, a grain size of the sensing material may be about 100 nm or less, but may not be limited thereto. Specifically, the grain size of the sensing material may be about 100 nm or less, about 90 nm or less, about 80 nm or less, about 70 nm or less, about 60 nm or less, about 50 nm or less, about 40 nm or less, about 30 nm or less, about 20 nm or less, about 10 nm or less, or about 5 nm or less. As for the detection, if the grain size is adjusted to 100 nm or less, the specific surface area to which a sensing target material can be adsorbed increases, and, thus, the detectability is improved. Particularly, when the grain size is 5 nm, the detectability is dramatically improved. Particularly, if a binary material or a ternary material is used as a sensing material and the grain size is 100 nm or less, an interface gap between the components remarkably increases, which results in an increase in an adsorption site for the sensing target material, and, thus, the detectability is improved.

In an embodiment of the present disclosure, the sensing material refers to a material constituting the nanostructure that is a final product. The sensing material is a material that can be scattered in many directions to apply the ion bombardment occurring during physical ion etching.

In an embodiment of the present disclosure, the sensing material may include at least one selected from a metal, a metal oxide, a metal sulfide, and a polymer, but may not be limited thereto. Specifically, the sensing material may include at least one metal selected from the group consisting of Au, Ag, Cu, Al, Ni, Pt, Pd, Sn, Mo, Ti, Cr, Mn, Fe, Co, Zn, In, W, Ir and Si, but may not be limited thereto. More specifically, the metal may include a binary material (bimetal) selected from the group consisting of Au—Cu, Au—Pt, Au—Ni, Au—Ag, Au—Pd, Pd—Ag, Ni—Sn, Mo—Ni, Au—Al, Au—Sn, Au—Mo, Au—Ti, Au—Cr, Au—Mn, Au—Fe, Au—Co, Au—Zn, Au—In, Au—W, Au—Ir, Au—Si, Ag—Cu, Ag—Al, Ag—Ni, Ag—Pt, Ag—Pd, Ag—Sn, Ag—Mo, Ag—Ti, Ag—Cr, Ag—Mn, Ag—Fe, Ag—Zn, Ag—In, Ag—W, Ag—Ir, Ag—Si, Sn—Ni, Sn—W, Sn—Cu and W—Pt or a ternary material (trimetal) selected from the group consisting of Au—Sn—Ni, Au—Sn—W, Au—Sn—Cu, Au—Ag—Cu, Au—Cu—Pt, Au—Ag—Pt, Au—Ag—Pd, Au—Cu—Pd, Ag—Cu—Pt, Ag—Cu—Pd, Pt—Sn—Ni, Pt—Sn—W and Pt—Sn—Cu, but may not be limited thereto.

In an embodiment of the present disclosure, the sensing material may include a binary material including SnO₂₍₁₋ₐ₎/NiOₐ, SnO₂₍₁₋ₐ₎/WO₃, SnO₂₍₁₋ₐ₎/CuOₐ, SnO₂₍₁₋ₐ₎/Auₐ, WO₃₍₁₋ₐ₎/Auₐ or WO₃₍₁₋ₐ₎/Ptₐ or a ternary material including SnO_{2(1-b-c)}/NiO_{b}/Au_{c}, SnO_{2(1-b-c)}/WO_{3b}/Au_{c} or SnO_{2(1-b-c)}/WO_{3b}/Pt, and 0≤a≤0.5, 0≤b+c<1, 0≤b≤0.5, and 0≤c≤0.5. Herein, a, b and c are molar ratio.

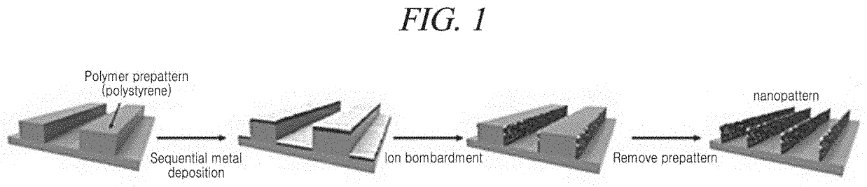

Referring to FIG. 1, a nanostructure containing multiple components can be obtained by depositing a multicomponent sensing material on a substrate and then re-depositing the multicomponent sensing material on an outer surface of a prepattern by an ion etching process.

In an embodiment of the present disclosure, the sensing material may sense a gas or a liquid. Specifically, the sensing material may sense a member selected from the group consisting of H₂, H₂S, CO, CO₂, water vapor, O₂, N₂, aromatic compounds (for non-limiting example: benzene, toluene, etc.) and VOC, but may not be limited thereto. Further, the sensing material may sense blood, biomolecules, bacteria, acetone or alcohols, but may not be limited thereto.

In an embodiment of the present disclosure, a grain size of the sensing material may be about 100 nm or less, a grain interface gap of the sensing material may be about 50 nm or less, an aspect ratio of the nanostructure may be about 1 or more, and a line width of the nanostructure may be about 50 nm or less, but may not be limited thereto. Specifically, the grain size of the sensing material may be about 10 nm or less, the grain interface gap of the sensing material may be about 5 nm or less, the aspect ratio of the nanostructure may be about 10 or more, and the line width of the nanostructure may be about 20 nm or less. More specifically, the grain size of the sensing material may be about 5 nm or less, the grain interface gap of the sensing material may be about 2 nm or less, the aspect ratio of the nanostructure may be about 30 or more, and the line width of the nanostructure may be about 10 nm or less. More specifically, the grain size of the sensing material may be from about 0.1 nm to about 5 nm, the grain interface gap of the sensing material may be from about 0.1 nm to about 2 nm, the aspect ratio of the nanostructure may be from about 30 to about 100, and the line width of the nanostructure may be from about 1 nm to about 10 nm. The sensor according to an embodiment of the present disclosure includes a nanostructure having an aspect ratio of 1 or more and a line width of 50 nm or less. This nanostructure cannot be manufactured by conventional technologies, but can be manufactured only by applying ion bombardment of the present disclosure and thus can show high affinity and adsorbability to a H₂S gas. Also, the sensor according to an embodiment of the present disclosure can adjust an interface gap to 50 nm or less. Therefore, if a binary or ternary sensing material is used, a joint portion between sensing materials increases, and, thus, high adsorbability and affinity to H₂S gas molecules can be achieved. That is, in the sensor according to an embodiment of the present disclosure, the nanostructure can be easily manufactured by applying ion bombardment to the binary or ternary sensing material and the interface gap can be adjusted to as small as 50 nm or less. Thus, the availability as a gas sensor can be improved.

In an embodiment of the present disclosure, the nanostructure may have a response amplitude (Rₐᵢᵣ/Rₐ) of 40 or more, a response time of less than about 100 seconds, and a recovery time of less than about 250 seconds when a hydrogen sulfide gas is detected, but may not be limited thereto.

In an embodiment of the present disclosure, the at least one nanostructure may have a line width of from about 5 nm to about 100 μm and a height of from about 10 nm to about 1000 μm, but may not be limited thereto. Further, the nanostructure can be prepared as a large-area nanochannel having a height of from about 10 nm to about 1000 μm and a line width of from about 5 nm to about 100 μm in a uniform manner by ion etching of a sensing material layer having a small thickness in the range of from about 5 nm to about 50 nm, and, thus, the surface area can increase. Also, the height can be easily adjusted by performing additional etching, and, thus, an increase in surface area can also be adjusted. Therefore, it can be usefully applied for miniaturization and integration of a sensor.

A second aspect of the present disclosure provides a method of manufacturing a sensor according to the first aspect of the present disclosure, including (a) depositing a sensing material on a substrate on which a prepattern is formed, (b) re-depositing the sensing material on the side of the prepattern by an ion etching process to form a nanopattern; and (c) removing the prepattern by an ion etching process to form nanostructures.

In an embodiment of the present disclosure, after the process (c), the method may further include (d) forming a second prepattern at a different angle from the nanopattern on the substrate on which the nanopattern has been formed and depositing the sensing material on the substrate, (e) re-depositing the sensing material on the side of the second prepattern by an ion etching process to form a second nanopattern, and (f) removing the second prepattern by an ion etching process.

In an embodiment of the present disclosure, the second prepattern may have an angle of from about 70° to about 90°, specifically from about 80° to about 90° and more specifically from about 85° to about 90°, with respect to the first prepattern.

Specifically, a prepattern is formed on a substrate on which a sacrificial layer has been coated by a lithography process. A photolithography process is a process in which a photomask is placed on a substrate on which a prepattern material has been formed and UV light is irradiated thereto to selectively remove the deposited prepattern material and thus form a prepattern, and a general photolithography process is used. After the sensing material is deposited on the substrate on which the prepattern has been formed as described above, the sensing material is re-deposited on the side of the prepattern by an ion etching process. After the prepattern is removed, a line-shaped nanopattern having a high aspect ratio and a high resolution is formed. To manufacture a mesh-like nanostructure, a prepattern may be formed with rotation of 90° on the line-shaped nanopattern by a photolithography process. After the sensing material is deposited on the substrate on which the second prepattern has been formed as described above, the sensing material is re-deposited on the side of the second prepattern by an ion etching process. After the prepattern is removed, a lattice-like nanostructure having a high aspect ratio and a high resolution is formed.

In an embodiment of the present disclosure, the method of manufacturing a sensor may include (a-1) adjusting a tilt angle of the prepattern by asymmetrically etching one side of the prepattern formed on the substrate at an angle of from about 30° to about 50° for from about 1 minute to about 30 minutes, (b-1) exposing the substrate by removing a portion where the prepattern has not been formed, (c-1) depositing the sensing material on the prepattern whose tilt angle has been adjusted, and (d-1) removing the prepattern to obtain a nanostructure that is tilted at from about 30° to about 89° with respect to the substrate.

In an embodiment of the present disclosure, the method of manufacturing a sensor may include (a-2) adjusting a tilt angle of the prepattern by asymmetrically etching one side of the prepattern transferred onto the substrate at an angle of from about 50° to about 80° for from about 1 minute to about 30 minutes, (b-2) exposing the substrate by removing a portion where the prepattern has not been transferred, (c-2) depositing the sensing material on the prepattern whose tilt angle has been adjusted, and (d-2) removing the prepattern to obtain a nanostructure whose partial upper portion is folded at from about 30° to about 89° with respect to the substrate.

The method of manufacturing a sensor according to an embodiment of the present disclosure will be described in detail. A polystyrene prepattern is transferred onto an ITO substrate using a line-patterned polydimethylsiloxane (PDMS) mold. Then, the prepattern is asymmetrically etched by ion milling, and the polymer is vertically etched using an RIE process to expose the ITO substrate on the bottom. Here, a tilted line pattern and a curved line pattern can be obtained by setting an asymmetric etching angle to 40° and 60°. Then, the substrate is tilted at about 16° so that the ITO on the bottom is scattered by an ion etching process and attached to only one side of the asymmetrically etched prepattern. Here, an angle of the finally obtained line-shaped nanopattern can be adjusted by adjusting a time of the ion etching process for each angle. Finally, polystyrene of the prepattern is removed by an RIE process to obtain a line-shaped nanostructure that is tilted or curved.

In the first aspect and the second aspect, all matters common to each other can be applied to each other, though descriptions thereof are omitted herein.

In an embodiment of the present disclosure, the ion etching process for generating an ion bombardment is performed by ion milling as a physical method. As for the ion milling, if an ion bombardment is generated by applying high energy to light ions, the wide angle distribution of the polycrystalline orientation becomes narrower to reduce the angle at which particles of the sensing material are scattered, thus making it difficult to attach the particles of the sensing material to the outer surface of the prepattern. Therefore, desirably, a physical ion etching process is performed by generating plasma using a heavy gas such as argon under a process pressure of from about 0.001 mTorr to about 700 Torr and then accelerating the plasma to from about 100 V to about 2,000 V. In the physical etching process, if ion etching is performed using plasma accelerated to more than 2,000 V, particles of the sensing material may be scattered from the sensing material layer at a vertical angle equal to the ion incidence direction, and, thus, the amount of particles attached to the outer surface of the prepattern may be small. If ion etching is performing using plasma accelerated to less than 100 V, the etching rate of the sensing material layer may be low, and, thus, the operating efficiency may be degraded.

In an embodiment of the present disclosure, the deposition of the sensing material may be typically performed by a method selected from the group consisting of chemical vapor deposition (CVD), atomic layer deposition, sputtering, laser ablation, arc discharge, plasma deposition, thermal chemical vapor deposition and e-beam evaporation, but may not be limited thereto.

In an embodiment of the present disclosure, the prepattern may be made of a polymer, and any polymer that can be used in a lithography process may be used without limitation. Specifically, the polymer may be selected from the group consisting of polystyrene, chitosan, polyvinyl alcohol, polymethylmethacrylate (PMMA), polyvinyl pyrrolidone, photoresist (PR) and mixtures thereof, but may not be limited thereto. The prepattern may be formed by spin coating or spray coating, but may not be limited thereto. Since the shape of the formed prepattern determines the shape of a nanostructure to be manufactured, nanostructures of various shapes and sizes can be easily manufactured by controlling the shape of the prepattern using various lithography processes. The above-described lithography process may be a conventional lithography process and specifically, it may be performed by at least one process selected from the group consisting of nanoimprint, soft lithography, block copolymer lithography, light lithography and capillary lithography. Particularly, the prepattern obtained by patterning using a lithography process can further be controlled to have various shapes and sizes depending on reactive ion etching (RIE) conditions and a polymer layer around the prepattern. For example, in reactive ion etching under a high vacuum of 0.1 mTorr to 0.001 mTorr, only anisotropic etching, i.e., etching of the bottom, can be performed, but in reactive ion etching under a low vacuum of 0.01 Torr to 0.1 Torr, isotropic etching, i.e., etching in all directions, can be performed. For this reason, when the prepattern is additionally ion-etched under a low vacuum, the overall height and diameter of the prepattern decrease. Thus, only the prepattern remains after the polymer layer around the prepattern is completely removed. Further, the size of the patterned polymer structure can be controlled depending on the thickness of the polymer layer coated on the substrate. If the prepattern layer has a small thickness, the prepattern layer may be removed within a short reactive ion etching time and only the prepattern may remain, and, thus, a cup-shaped polymer structure pattern may be formed within a short time. However, if the prepattern layer has a large thickness, reactive ion etching may be performed for a long time, and, thus, the prepattern may be entirely etched so that the entire size of the prepattern may decrease and the prepattern may have a small diameter. Further, the shape of the prepattern may be selected from the group consisting of line pattern, lattice shape, curved shape, cylinder shape, square column shape, reciprocal cone shape, cuboid shape, top shape, cup shape and c-shape.

Specifically, when the prepattern is removed, only the polymer prepattern is removed by dry etching or wet etching to obtain a nanostructure. The dry etching or wet etching may be performed by a conventional etching process capable of removing a polymer.

In an embodiment of the present disclosure, the line width and the height of the prepattern may be from about 1 nm to about 100 μm and from about 10 nm to about 1000 μm, respectively. Specifically, the line width and the height may be from about 1 nm to about 10 μm and from about 10 nm to about 100 μm, respectively, and more specifically, the line width and the height may be from about 1 nm to about 100 nm and from about 200 nm to about 800 nm, respectively.

In an embodiment of the present disclosure, the prepattern may be formed by forming a block copolymer pattern on the substrate and then removing a part of a polymer from the block copolymer by an ion etching process.

In an embodiment of the present disclosure, the block copolymer may be PS-b-PMMA, the PS-b-PMMA block copolymer may have about 270 kg/mol to about 280 kg/mol and the prepattern may have a lamella shape, and the PS-b-PMMA block copolymer may have about 65 kg/mol to about 140 kg/mol and the prepattern may have a nanoporous cylinder shape, but may not be limited thereto. Specifically, if a block copolymer is used as a material of a prepattern, the prepattern may have a lamella shape and a nanoporous cylinder shape which cannot be obtained when the prepattern is made of a single polymer. Specifically, when PS-b-PMMA is used as a block copolymer, the amount of the PS-b-PMMA block copolymer may be adjusted to from 270 kg/mol to 280 kg/mol to form the prepattern into a lamella shape, or the amount of the PS-b-PMMA block copolymer may be adjusted to from 65 kg/mol to 140 kg/mol to form the prepattern into a nanoporous cylinder shape. Accordingly, a nanostructure can also be manufactured into a lamella shape or a nanoporous cylinder shape.

In an embodiment of the present disclosure, the sensing material may include at least one selected from a metal, a metal oxide, a metal sulfide, and a polymer, but may not be limited thereto. Specifically, the sensing material may include at least one metal selected from the group consisting of Au, Ag, Cu, Al, Ni, Pt, Pd, Sn, Mo, Ti, Cr, Mn, Fe, Co, Zn, In, W, Ir and Si, but may not be limited thereto. Specifically, a multicomponent nanostructure may have catalytic properties unlike a conventional nanostructure made of a single component, and the manufacturing method of the present disclosure can manufacture a nanostructure that has uniformity, resolution and aspect ratio equivalent to the conventional ones and an inner structure which can be controlled to have a layered structure, a mixed structure, a core-shell structure, or the like.

In an embodiment of the present disclosure, the sensing material may include at least one metal selected from the group consisting of Sn, Ni, W, Cu, Au, and Pt, and the method may include sequentially depositing at least one metal selected from the group consisting of Sn, Ni, W, Cu, Au, and Pt, re-depositing each of the deposited layers on the side of the prepattern by the ion etching process to form the nanopattern, removing the prepattern by the ion etching process, and annealing the nanopattern. Specifically, the sensing material prepared by annealing may include a binary material including SnO₂₍₁₋ₐ₎/NiOₐ, SnO₂₍₁₋ₐ₎/WO₃ₐ, SnO₂₍₁₋ₐ₎/CuOₐ, SnO₂₍₁₋ₐ₎/Auₐ, WO₃₍₁₋ₐ₎/Auₐ or WO₃₍₁₋ₐ₎/Ptₐ or a ternary material including SnO_{2(1-b-c)}/NiO_{b}/Au_{c}, SnO_{2(1-b-c)}/WO_{3b}/Au_{c} or SnO_{2(1-b-c)}/WO_{3b}/Pt_{c}, and 0≤a≤0.5, 0≤b+c<1, 0≤b≤0.5, and 0≤c≤0.5, but may not be limited thereto. Herein, a, b and c are molar ratio.

In an embodiment of the present disclosure, an order of the deposition, a thickness of the deposition, and the number of the deposition is adjusted while depositing the sensing material or an angle of the ion etching process or a time of the ion etching process is adjusted after the deposition, in order to change a component, a content ratio, or a shape of the sensing material to be re-deposited.

Hereinafter, the present disclosure will be explained in more detail with reference to Examples. However, the following Examples are illustrative only for better understanding of the present disclosure but do not limit the present disclosure.

### EXAMPLES

### Example 1: Preparation of Nanostructure Containing SnO₂

A prepattern made of polystyrene (PS) was formed on an SiO₂/Si wafer substrate by capillary force lithography. Then, Sn as a hydrogen sulfide sensing material was deposited to 30 nm on the substrate and the deposited Sn was etched using an Ar ion bombardment to re-deposit the metal on the side of the PS prepattern. Then, the PS prepattern was removed by an ion etching process and thermal annealing was performed to the re-deposited Sn metal to obtain a line-shaped nanostructure containing SnO₂ with a thickness of 15 nm to 20 nm and a height of ˜230 nm (FIG. 1).

The Sn metals had a grain size of 5 nm or less, which resulted in a large specific surface area between the metals.

### Examples 2 to 4: Preparation of Nanostructure Containing Binary Material

Nanostructures were prepared by the same method as in Example 1 except that SiO₂/NiO and SnO₂/Au were used as a sensing material.

Specifically, (i) a line-shaped nanostructure containing SnO₂/NiO (molar ratio of 28:2) was obtained by sequentially depositing Ni, Sn and Ni to 1 nm, 28 nm and 1 nm, respectively, on the substrate, etching the deposited metals using an Ar ion bombardment to re-deposit the metals on the side of the PS prepattern, and performing thermal annealing (Example 2).

(ii) A line-shaped nanostructure containing SnO₂/Au (molar ratio of 29:1) was obtained by sequentially depositing Au, Sn and Au to 0.5 nm, 29 nm and 0.5 nm, respectively, on the substrate, etching the deposited metals using an Ar ion bombardment to re-deposit the metals on the side of the PS prepattern, and performing thermal annealing (Example 3). Also, (iii) a line-shaped nanostructure containing SnO₂/Au (molar ratio of 28:2) was prepared by the same method as in Example 3 except that Au, Sn and Au were deposited to 1 nm, 28 nm and 1 nm, respectively, on the substrate (Example 4).

The metals in Examples 2 to 4 had a grain size of 5 nm or less, which resulted in a large specific surface area between the metals.

### Test Example 1

Sensing of Hydrogen Sulfide Gas Using Nanostructure (SnO₂) of Example 1

To test the sensitivity to a hydrogen sulfide (H₂S) gas, the dynamic sensing response of a sensor including the line-shaped nanostructure containing SnO₂ as prepared in Example 1 was tested under air. A constant bias was applied to a 4-probe resistance type sensor (Au/Ti electrode), a change in electrical resistance of the sensor depending on the exposure to the H₂S gas was monitored and a sensing signal was recorded. The sample was simultaneously loaded into a gas sensing chamber and sensing signals of the nanostructure were measured using multi-channel sensing systems.

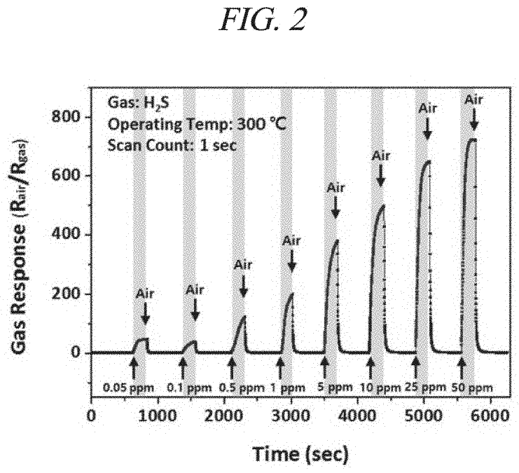

While the concentration of the H₂S gas was changed in the range of from 0.05 ppm to 50 ppm, the response amplitude (Rₐᵢᵣ/Rₐ) of the nanostructure of Example 1 was tested per second. As a result, the nanostructure showed a response amplitude of 200, a response time of 20 seconds and a recovery time of 205 seconds at 1 ppm of H₂S gas, which means that the nanostructure showed excellent response to even as little as 1 ppm of H₂S gas as well as short response time/recovery time. Further, the nanostructure showed a response amplitude of 378, a response time of 9 seconds and a recovery time of 70 seconds at 5 ppm of H₂S gas, which means that the nanostructure showed remarkably excellent response as well as remarkably short response time/recovery time (FIG. 2).

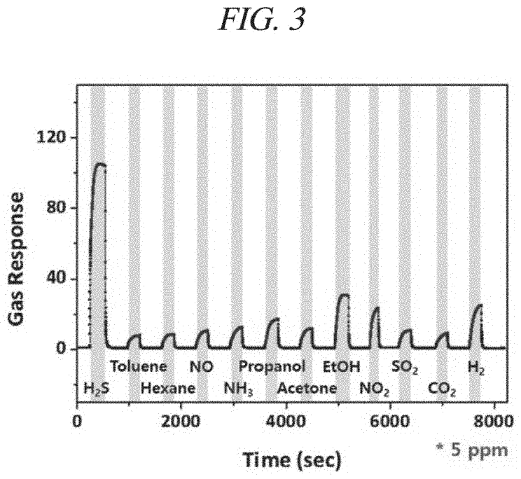

Also, the selectivity to the H₂S gas was verified by testing the sensitivity of the nanostructure of Example 1 to various gases including the H₂S gas, toluene, hexane, carbon monoxide, ammonia, propane, acetone, ethanol, nitrogen dioxide, sulfur dioxide, carbon dioxide, and hydrogen. Each of the gases was injected at a concentration of 5 ppm, and the response amplitude (Rₐᵢᵣ/Rₐ) of the nanostructure of Example 1 to each of the gases was checked. As a result, the nanostructure of Example 1 showed a response amplitude of 105 to the H₂S gas, but did not show a remarkable response amplitude to the other gases. Also, the nanostructure of Example 1 showed excellent results in terms of response time/recovery time to the H₂S gas compared to the other gases (FIG. 3).

Based on the above-described result, it was verified that the sensor including the nanostructure of Example 1 can be commercialized as a H₂S gas sensor with best performance.

### Test Example 2

Sensing of Hydrogen Sulfide Gas Using Nanostructures (SnO₂/NiO, SnO₂/Au) of Examples 2 to 4

To test the sensitivity to a hydrogen sulfide (H₂S) gas, the dynamic sensing response of a sensor including each of the line-shaped nanostructures as prepared in Examples 2 to 4 was tested under air. A constant bias was applied to a 4-probe resistance type sensor (Au/Ti electrode), a change in electrical resistance of each of the sensors depending on the exposure to the H₂S gas was monitored and a sensing signal was recorded. The samples were simultaneously loaded into a gas sensing chamber and sensing signals of the nanostructures were measured using multi-channel sensing systems.

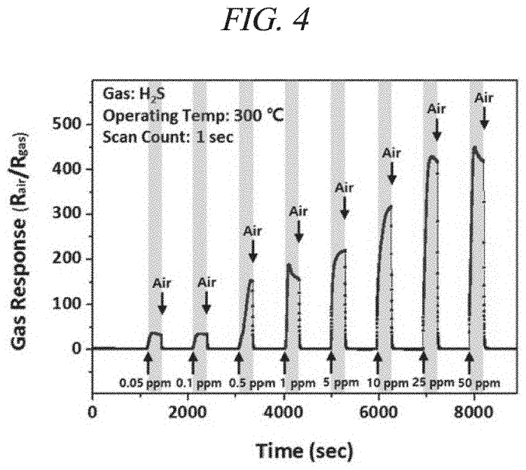

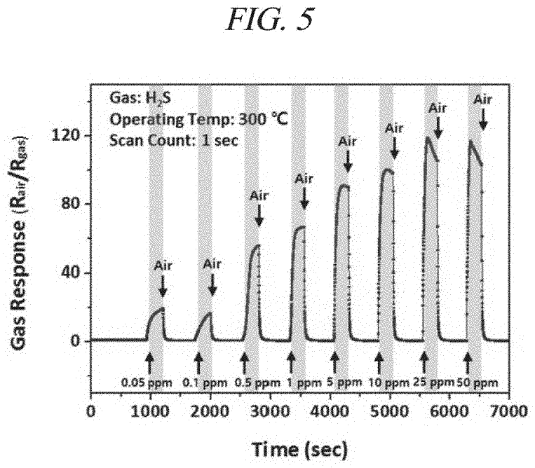

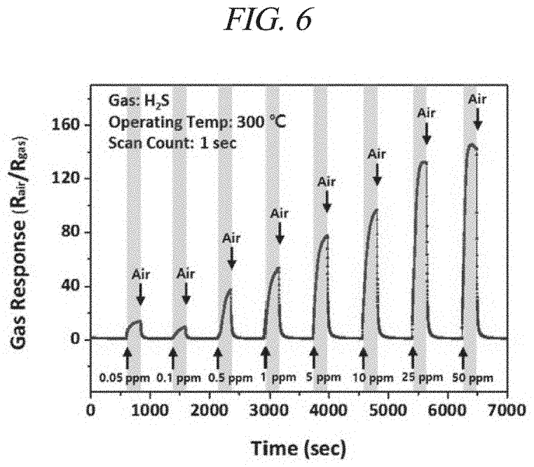

While the concentration of the H₂S gas was changed in the range of from 0.05 ppm to 50 ppm, the response amplitude (Rₐᵢᵣ/Rₐ) of the nanostructures of Examples 2 to 4 was tested per second. As a result, all the nanostructures of Examples 2 to 4 showed a significant response amplitude of 40 or more and short response time/recovery time at 0.5 ppm of H₂S gas, which verifies that all the nanostructures have excellent sensitivity to the H₂S gas and all the nanostructures containing a binary material of Examples 2 to 4 can be usefully used to detect H₂S (FIG. 4 to FIG. 6). Specifically, the nanostructure of Example 2 showed a response amplitude of about 150 at 0.5 ppm of H₂S gas, a response amplitude of about 200 at 1 ppm of H₂S gas, and a response amplitude of about 230, a response time of about 5 seconds or less and a recovery time of 219 seconds or less at 5 ppm of H₂S gas. Also, the nanostructure of Example 3 showed a response amplitude of about 55 at 0.5 ppm of H₂S gas, a response amplitude of about 65 at 1 ppm of H₂S gas, and a response amplitude of about 90, a response time of about 68 seconds or less and a recovery time of 20 seconds or less at 5 ppm of H₂S gas. Further, the nanostructure of Example 4 showed a response amplitude of about 40 at 0.5 ppm of H₂S gas, a response amplitude of about 50 at 1 ppm of H₂S gas, and a response amplitude of about 80, a response time of about 139 seconds or less and a recovery time of 41 seconds or less at 5 ppm of H₂S gas.

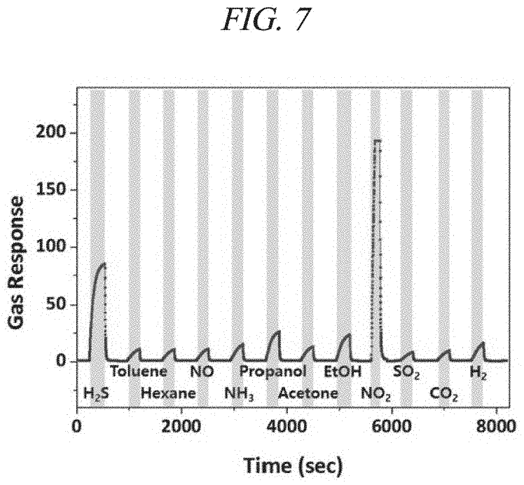

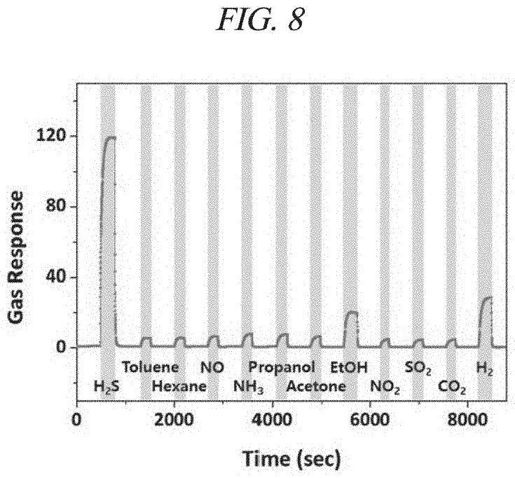

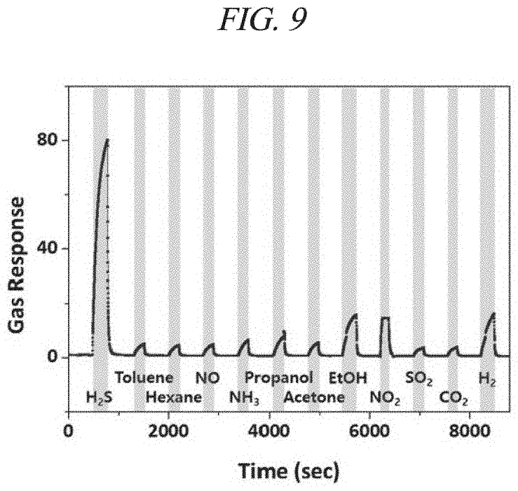

Also, the selectivity to the H₂S gas was verified by testing the sensitivity of the nanostructures of Examples 2 to 4 to various gases including the H₂S gas, toluene, hexane, carbon monoxide, ammonia, propane, acetone, ethanol, nitrogen dioxide, sulfur dioxide, carbon dioxide, and hydrogen. Each of the gases was injected at a concentration of 5 ppm, and the response amplitude (Rₐᵢᵣ/Rₐ) of the nanostructures of examples 2 to 4 to each of the gases was checked. As a result, the nanostructure of Example 2 showed a response amplitude of 80 or more to the H₂S gas and a response amplitude of 200 to nitrogen dioxide, which verifies that it can be used to detect hydrogen sulfide and nitrogen dioxide. Also, the nanostructures of Examples 3 and 4 showed response amplitudes of 120 and 80, respectively, to the H₂S gas, but did not show a remarkable response amplitude to the other gases. Further, all the nanostructures of Examples 2 to 4 showed excellent results in terms of response time/recovery time to the H₂S gas compared to the other gases (FIG. 7 to FIG. 9).

Based on the above-described result, it was verified that the sensors including the nanostructures of Examples 2 to 4 can be commercialized as a H₂S gas sensor with best performance.

### Example 5: Preparation of Nanostructure Containing SnO₂/Pt, SnO₂/Au, WO₃, WO₃/Au or WO₃/Pt

A nanostructure was prepared by the same method as in Example 1 except the kind of a H₂S sensing material to be deposited. Specifically, Sn:Pt were deposited at a molar ratio of 25:1, Sn:Au were deposited at a molar ratio of 25:1, Sn:Au were deposited at a molar ratio of 25:0.5, W was deposited alone, W:Au were deposited at a molar ratio of 25:1 and W:Pt were deposited at a molar ratio of 25:1, followed by an Ar ion bombardment. Then, thermal annealing was performed to obtain a line-shaped nanostructure with a thickness of 15 nm to 20 nm and a height of ˜230 nm.

### Comparative Example: Preparation of Nanostructure Containing Au/Cu or Au/Pd

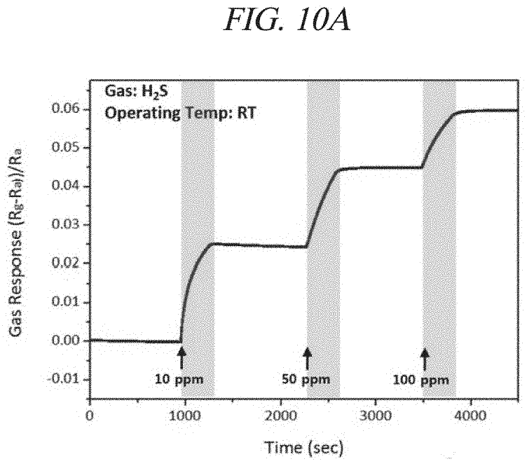

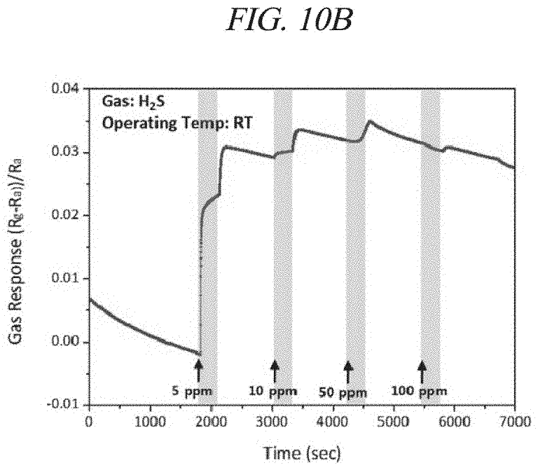

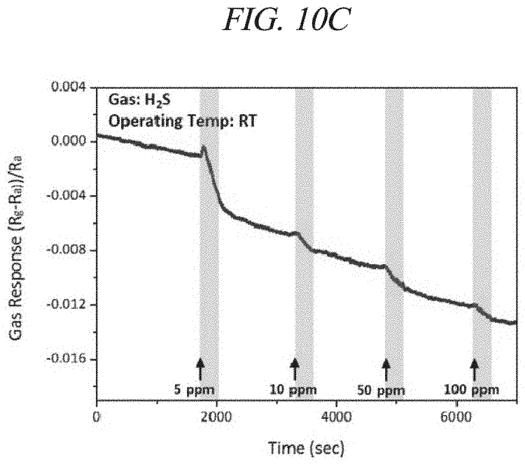

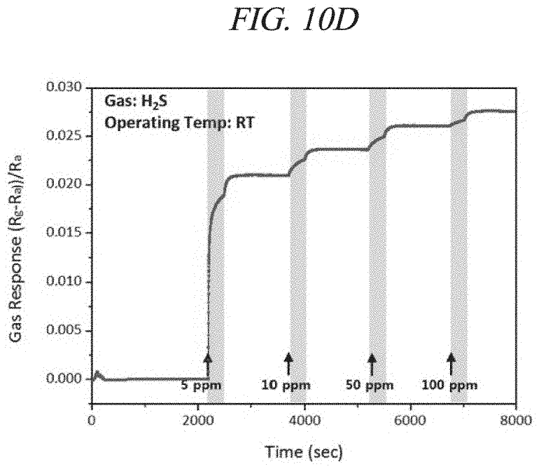

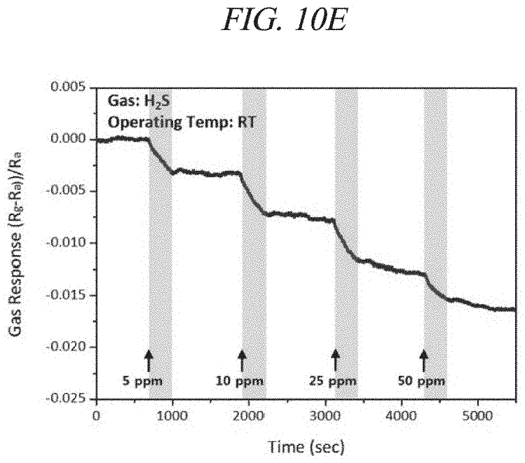

A nanostructure was prepared by the same method as in Example 1 except the kind of a H₂S sensing material to be deposited. Specifically, Au was deposited alone (FIG. 10A), Au:Cu were deposited at a molar ratio of 1:1 (FIG. 10B), Au:Pd were deposited at a molar ratio of 1:1 (FIG. 10C), Au:Pd were deposited at a molar ratio of 7:3 (FIG. 10D) and Au:Pd were deposited at a molar ratio of 9:1 (FIG. 10E), followed by an Ar ion bombardment. Then, thermal annealing was performed to obtain a line-shaped nanostructure with a thickness of 15 nm to 20 nm and a height of ˜230 nm.

### Test Example 3

Sensing of Hydrogen Sulfide Gas Using Nanostructures of Example 5 and Comparative Example

To test the sensitivity to a hydrogen sulfide (H₂S) gas, the dynamic sensing response of a sensor including each of the line-shaped nanostructures as prepared in Example 3 and Comparative Example was tested under air. A constant bias was applied to a 4-probe resistance type sensor (Au/Ti electrode), a change in electrical resistance of each of the sensors depending on the exposure to the H₂S gas was monitored and a sensing signal was recorded. The samples were simultaneously loaded into a gas sensing chamber and sensing signals of the nanostructures were measured using multi-channel sensing systems.

While the concentration of the H₂S gas was changed in the range of from 5 ppm to 100 ppm, the response amplitude ((R_{g}−Rₐ)/Rₐ) of the sensor including the nanostructure containing Au/Cu or Au/Pd of Comparative Example was tested per second. As a result, the nanostructure containing Au alone showed a response amplitude of more than 2 and long recovery time at 10 ppm of H₂S gas (FIG. 10A). Also, the binary component nanostructure containing Au/Cu showed a response amplitude of 4 or more and short response time at 5 ppm of H₂S gas but was not recovered well (FIG. 10B). The binary component nanostructure containing Au/Pd (molar ratio of 1:1) showed a response amplitude of almost 2 at 10 ppm of H₂S gas but was not recovered well (FIG. 10C). Further, the binary component nanostructures containing Au/Pd at molar ratios of 5:5, 7:3 and 9:1, respectively, showed different responses depending on the concentration of the H₂S gas. Furthermore, the nanostructure containing Au/Pd at a molar ratio of 9:1 compared with 5:5 and 7:3 showed a decrease in resistance value to the H₂S gas. However, all the nanostructures containing Au/Pd at molar ratios of 5:5, 7:3 and 9:1, respectively, did not show excellent results in terms of response time/recovery time (FIG. 10C to FIG. 10E).

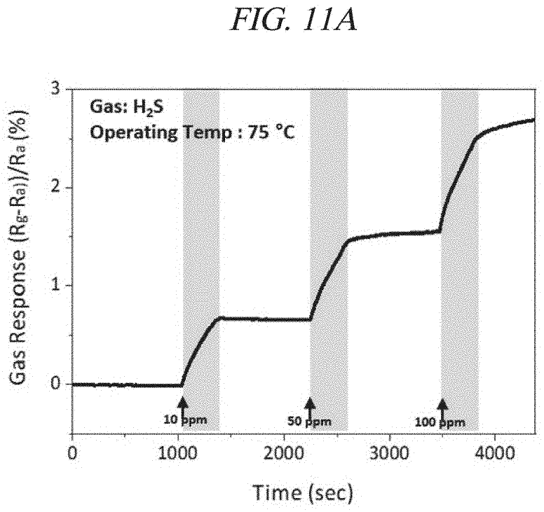

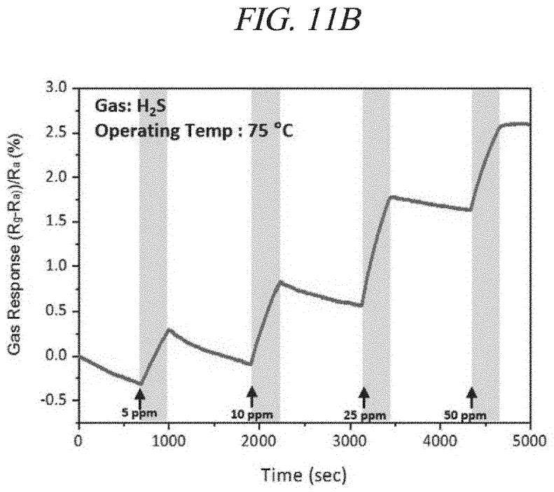

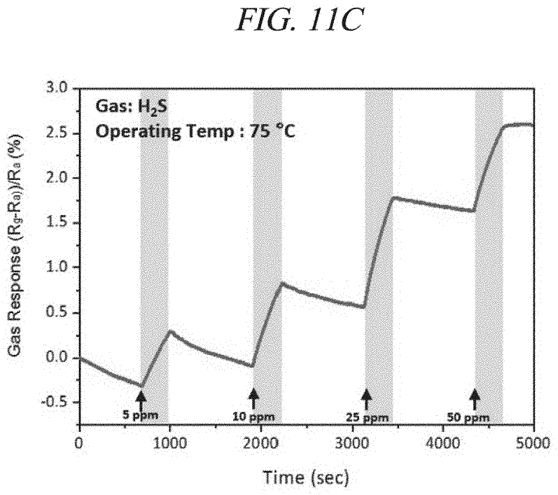

While the concentration of the H₂S gas was changed in the range of from 5 ppm to 50 ppm at 75° C., the response amplitude ((R_{g}−Rₐ)/Rₐ) of the sensor including the nanostructure containing Au/Pd of Comparative Example was tested per second. The binary component nanostructures containing Au/Pd at molar ratios of 5:5, 7:3 and 9:1, respectively, showed different responses depending on the concentration of the H₂S gas. All the three cases did not show excellent results in terms of response time/recovery time even at an operating temperature of 75° C. as in the case of room temperature (FIG. 11A to FIG. 11C).

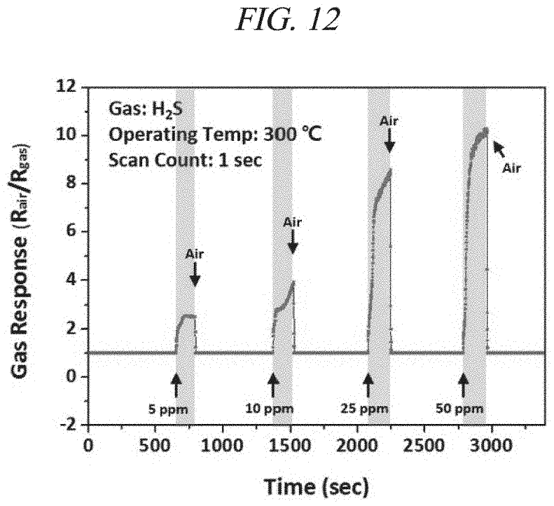

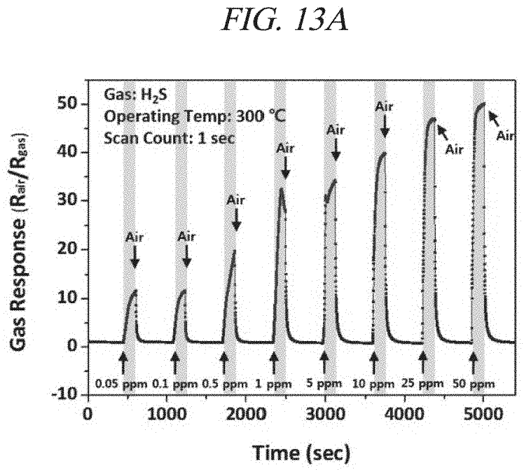

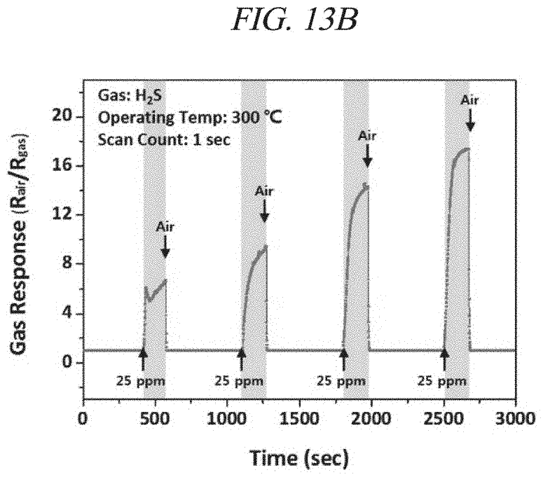

Meanwhile, the sensor including the nanostructure containing SnO₂/Pt, SnO₂/Au, WO₃, WO₃/Au or WO₃/Pt as prepared in Example 5 showed excellent effects. Specifically, the response amplitude (Rₐᵢᵣ/R_{gas}) of the nanostructure containing SnO₂/Pt to the H₂S gas having a concentration in the range of 0.05 ppm to 50 ppm at 300° C. was tested per second. The nanostructure containing SnO₂ showed a response amplitude of about 50 at 0.05 ppm of H₂S gas and a response amplitude of 720 or more at 50 ppm of H₂S gas (FIG. 2). Accordingly, it was verified that this nanostructure had the highest sensitivity to the H₂S gas compared with the other nanostructures. The nanostructure containing SnO₂/Pt (molar ratio of 25:1) showed a response amplitude of about 2 at 5 ppm of H₂S gas (FIG. 12). Further, the response amplitude (Rₐᵢᵣ/R_{gas}) of the nanostructure containing SnO₂/Au to the H₂S gas having a concentration in the range of 0.05 ppm to 50 ppm at 300° C. was tested per second. The nanostructure containing SnO₂/Au (molar ratio of 25:1) showed excellent sensitivity with a response amplitude of 10 or more at 0.05 ppm of H₂S gas and a response amplitude of 50 or more at 50 ppm of H₂S gas (FIG. 13A). The nanostructure containing SnO₂/Au (molar ratio of 25:0.5) smaller in amount of Au showed a response amplitude of about 6 at 5 ppm of H₂S gas and a response amplitude of 16 at 50 ppm of H₂S gas (FIG. 13B).

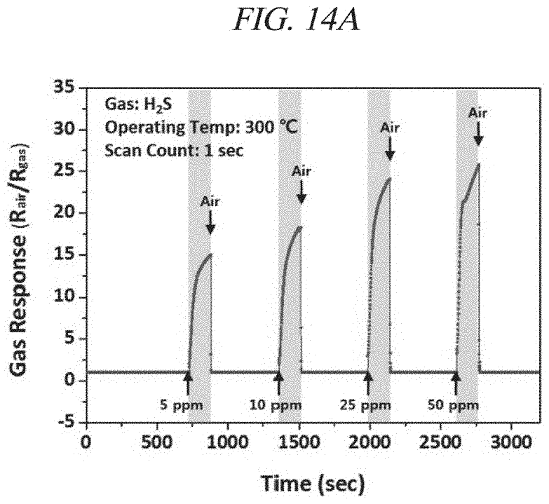

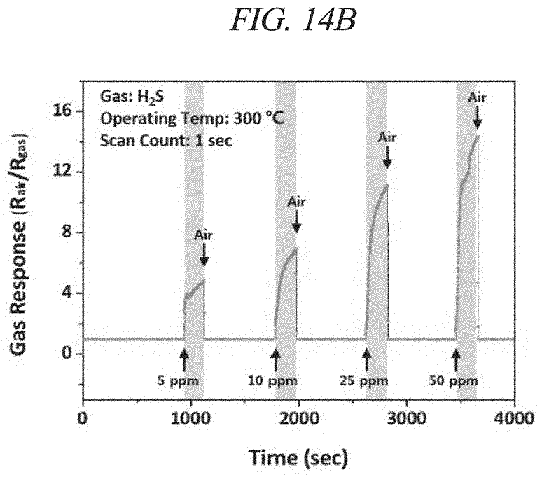

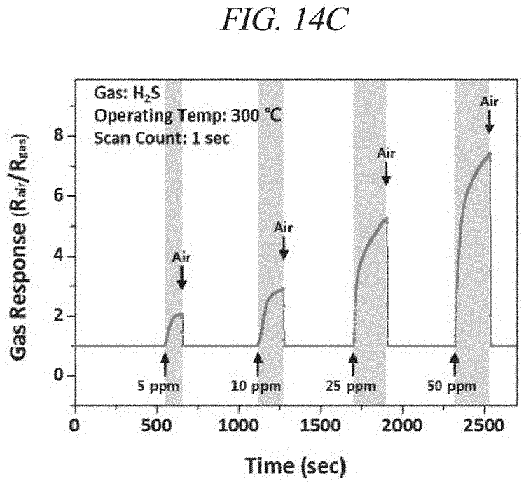

The response amplitude (Rₐᵢᵣ/R_{gas}) of the nanostructure containing WO₃, WO₃/Au or WO₃/Pt to the H₂S gas having a concentration in the range of 5 ppm to 50 ppm at 300° C. was tested per second. The nanostructure containing WO₃ showed a response amplitude of about 15 at 5 ppm of H₂S gas and a response amplitude of 25 or more at 50 ppm of H₂S gas (FIG. 14A). The nanostructure containing WO₃/Au (molar ratio of 25:1) showed a response amplitude of 4 at 5 ppm of H₂S gas (FIG. 14B). The nanostructure containing WO₃/Pt (molar ratio of 25:1) showed a response amplitude of about 1 at 5 ppm of H₂S gas and a response amplitude of about 7 at 50 ppm of H₂S gas (FIG. 14C).

Accordingly, it was verified that the sensor including the nanostructure of Example 3 had an excellent response amplitude and an excellent response time/recovery time compared with the sensor of Comparative Example.

### Test Example 4

Measurement of Tendency of Sensing Gas Using Nanostructure (SnO₂/NiO. SnO₂/Au)

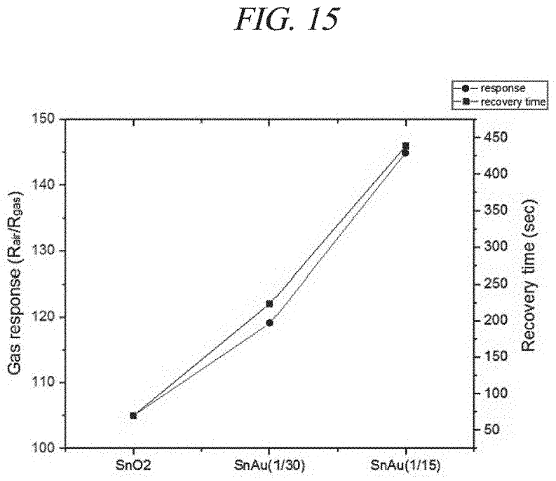

The affinity and adsorbability of nanostructures containing a sensing material to hydrogen sulfide gas molecules depending on the presence of gold (Au) were checked (FIG. 15). FIG. 15 shows the response amplitude and recovery time at 5 ppm of H₂S gas, and on the X-axis, SnO₂ represents a nanostructure containing SnO₂ only, SnAu(1/30) represents a nanostructure containing SnO₂/Au with a molar ratio of Sn:Au=30:1, and SnAu(1/15) represents a nanostructure containing SnO₂/Au with a molar ratio of Sn—Au=15:1. It can be seen that as for the nanostructures containing SnO₂/Au, as the amount of Au increases, the adsorbability to the hydrogen sulfide gas molecules increases, which results in an increase in response amplitude and sensitivity. Also, it can be seen that there is a tendency for the recovery time to increase due to the high adsorbability.

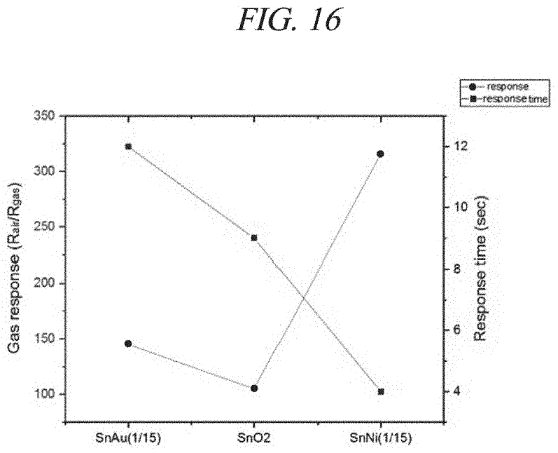

The adsorbability of nanostructures containing SnO₂, SnO₂/Au (molar ratio of 15:1) and SnO₂/NiO (molar ratio of 15:1) to hydrogen sulfide gas molecules were checked (FIG. 16). It was verified that the nanostructures containing SnO₂/Au (molar ratio of 15:1) and SnO₂/NiO (molar ratio of 15:1), respectively, showed a higher adsorbability than the nanostructure containing SnO₂ and the nanostructure containing SnO₂/NiO (molar ratio of 15:1) showed a remarkable adsorbability to hydrogen sulfide gas molecules compared with the nanostructure containing SnO₂/Au (molar ratio of 15:1). Based on this result, it was verified that Ni present in the form of oxide forms a P-N Junction together with SnO₂ and thus shows a high adsorbability and a fast response to the H₂S gas by means of P-N junction enhancement. Also, based on the above-described result, it can be seen that since the P-N Junction has electric charges, the effect can increase as the interface gap increases. Accordingly, the above-described result verifies that when the grain size of the sensing material in the nanostructures of Examples is adjusted to 100 nm or less and the grain interface gap is adjusted to 50 nm or less, excellent adsorbability and fast response time to hydrogen sulfide gas molecules can be achieved.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A sensor, comprising:
an array of at least one nanostructure including a sensing material.

2. The sensor of claim 1,
wherein the sensing material detects a hydrogen sulfide (H₂S) gas.

3. The sensor of claim 1,
wherein shapes of the nanostructures are selected from the group consisting of line pattern, lattice shape, curved shape, cylinder shape, square column shape, reciprocal cone shape, cuboid shape, top shape, cup shape and c-shape.

4. The sensor of claim 1,
wherein a grain size of the sensing material is 100 nm or less.

5. The sensor of claim 1,
wherein the sensing material includes at least one selected from a metal, a metal oxide, a metal sulfide, and a polymer.

6. The sensor of claim 5,
wherein the sensing material includes at least one metal selected from Au, Ag, Cu, Al, Ni, Pt, Pd, Sn, Mo, Ti, Cr, Mn, Fe, Co, Zn, In, W, Ir and Si.

7. The sensor of claim 5,
wherein the metal includes a binary material selected from the group consisting of Au—Cu, Au—Pt, Au—Ni, Au—Ag, Au—Pd, Pd—Ag, Ni—Sn, Mo—Ni, Au—Al, Au—Sn, Au—Mo, Au—Ti, Au—Cr, Au—Mn, Au—Fe, Au—Co, Au—Zn, Au—In, Au—W, Au—Ir, Au—Si, Ag—Cu, Ag—Al, Ag—Ni, Ag—Pt, Ag—Pd, Ag—Sn, Ag—Mo, Ag—Ti, Ag—Cr, Ag—Mn, Ag—Fe, Ag—Zn, Ag—In, Ag—W, Ag—Ir, Ag—Si, Sn—Ni, Sn—W, Sn—Cu and W—Pt; or a ternary material selected from the group consisting of Au—Sn—Ni, Au—Sn—W, Au—Sn—Cu, Au—Ag—Cu, Au—Cu—Pt, Au—Ag—Pt, Au—Ag—Pd, Au—Cu—Pd, Ag—Cu—Pt, Ag—Cu—Pd, Pt—Sn—Ni, Pt—Sn—W and Pt—Sn—Cu.

8. The sensor of claim 1,
wherein the sensing material includes a binary material including SnO₂₍₁₋ₐ₎/NiOₐ, SnO₂₍₁₋ₐ₎/WO₃ₐ, SnO₂₍₁₋ₐ₎/CuOₐ, SnO₂₍₁₋ₐ₎/Auₐ, WO₃₍₁₋ₐ₎/Auₐ or WO₃₍₁₋ₐ₎/Ptₐ; or a ternary material including SnO_{2(1-b-c}/NiO_{b}/Au_{c}, SnO_{2(1-b-c)}/WO_{3b}/Au_{c} or SnO_{2(1-b-c)}/WO_{3b}/Pt_{c}; and
wherein, 0≤a≤0.5, 0≤b+c<1, 0≤b≤0.5, and 0≤c≤0.5.

9. The sensor of claim 1,
wherein a grain size of the sensing material is 100 nm or less; and
wherein a grain interface gap of the sensing material is 50 nm or less.

10. The sensor of claim 1,
wherein an aspect ratio of the nanostructures is 1 or more; and
wherein a line width of the nanostructures is 50 nm or less.

11. The sensor of claim 1,
wherein the nanostructures have a response amplitude (Rₐᵢᵣ/Rₐ) of 40 or more, a response time of less than 100 seconds, and a recovery time of less than 250 seconds when a hydrogen sulfide gas is detected.

12. A method of manufacturing a sensor according to claim 1, comprising:
(a) depositing a sensing material on a substrate on which a prepattern is formed;
(b) re-depositing the sensing material on the side of the prepattern by an ion etching process to form a nanopattern; and
(c) removing the prepattern by an ion etching process to form nanostructures.

13. The method of claim 12,
wherein the sensing material is selected from the group consisting of a metal, a metal oxide, a metal sulfide, and a polymer.

14. The method of claim 12,
wherein the sensing material includes at least one metal selected from Au, Ag, Cu, Al, Ni, Pt, Pd, Sn, Mo, Ti, Cr, Mn, Fe, Co, Zn, In, W, Ir and Si.

15. The method of claim 14,
wherein the sensing material includes at least one metal selected from Sn, Ni, W, Cu, Au, and Pt;
wherein, the method includes:
sequentially depositing at least one metal selected from Sn, Ni, W, Cu, Au, and Pt;
re-depositing each of the deposited layers on the side of the prepattern by the ion etching process to form the nanopattern;
removing the prepattern by the ion etching process; and
annealing the nanopattern.

16. The method of claim 12,
wherein an order of the deposition, a thickness of the deposition, and the number of the deposition is adjusted while depositing the sensing material; or
an angle of the ion etching process or a time of the ion etching process is adjusted after the deposition, in order to change a component, a content ratio, or a shape of the sensing material to be re-deposited.
